(19) United States
(12) Patent Application Publication
(10) Pub. No.: US 2026/0293489 A1
(43) Pub. Date: Sep. 24, 2026

(54) DISPLAY DEVICE

(71) Applicant: WUHAN TIANMA MICROELECTRONICS CO., LTD., Wuhan (CN)

(72) Inventors: Hongchi ZHOU, Wuhan (CN); Bin XIONG, Wuhan (CN); Chujie YU, Wuhan (CN)

(73) Assignee: WUHAN TIANMA MICROELECTRONICS CO., LTD., Wuhan (CN)

(21) Appl. No.: 19/672,987

(22) Filed: May 11, 2026

(30) Foreign Application Priority Data
Dec. 25, 2025 (CN) 202511985816.9

(51) Int. Cl. H10K 59/60; G09G 3/00; G09G 3/3225; H10K 59/131

(52) U.S. Cl. CPC H10K 59/60; G09G 3/006; G09G 3/3225; H10K 59/131; G09G 2310/08; G09G 2320/041; G09G 2320/043

(57) ABSTRACT

Provided is a display device. The display device includes a display panel and a main controller. The display panel includes a display region and a non-display region connected to the display region and further includes multiple temperature-sensing devices. A temperature-sensing device includes a PN junction. The multiple temperature-sensing devices are located at different positions of the non-display region. The main controller is connected to the multiple temperature-sensing devices and is configured to sequentially acquire forward voltage drops across PN junctions of the temperature-sensing devices under a preset conduction current and determine, according to the forward voltage drops, temperatures at the different positions of the non-display region where the temperature-sensing devices are located.

### CROSS-REFERENCE TO RELATED APPLICATION

This application claims priority to Chinese Patent Application No. 202511985816.9, filed on Dec. 25, 2025, the disclosure of which is incorporated herein by reference in its entirety.

### TECHNICAL FIELD

Embodiments of the present application relate to the field of panel display technologies and, in particular, to a display device.

### BACKGROUND

With the advancement of display technologies, application scenarios requiring display have become increasingly diverse. Given the significant temperature variations involved in the actual operating environments of display screens, temperature monitoring and overheat protection of the display screens have emerged as critical priorities in the display industry to prevent damage caused by extreme temperatures.

Existing temperature monitoring solutions for the display screens typically involve mounting temperature-sensing elements (such as temperature-sensing integrated circuits (ICs) and thermistors) onto printed circuit boards. The temperature-sensing elements are separated from the display screens by structures such as the printed circuit boards, resulting in reduced accuracy in detecting the surface temperatures of display panels. As a result, real-time power reduction and overheat protection based on such data are less effective, thereby adversely affecting the reliability and service life of the display screens.

### SUMMARY

The present application provides a display device. By directly integrating temperature-sensing devices on a display panel, temperatures at various positions of the display panel can be accurately detected, thereby performing accurate and effective temperature detection and helping improve the reliability and service life of the display panel.

Embodiments of the present application provide a display device. The display device includes a display panel and a main controller, the display panel includes a display region and a non-display region connected to the display region and further includes multiple temperature-sensing devices, a temperature-sensing device of the multiple temperature-sensing devices includes a PN junction, and the multiple temperature-sensing devices are located at different positions of the non-display region.

The main controller is connected to the multiple temperature-sensing devices, and the main controller is configured to sequentially acquire forward voltage drops across PN junctions of the multiple temperature-sensing devices under a preset conduction current and determine, according to the forward voltage drops, temperatures at the different positions of the non-display region where the multiple temperature-sensing devices are located.

### BRIEF DESCRIPTION OF DRAWINGS

FIG. 1 is a diagram illustrating the rear structure of a vehicle-mounted organic light-emitting diode (OLED) display module in the related art.

FIG. 2 is a diagram illustrating the structure of a display panel in a display device according to an embodiment of the present application.

FIG. 3 is another diagram illustrating the structure of a display panel in a display device according to an embodiment of the present application.

FIG. 4 is an equivalent circuit diagram of a temperature-sensing system in the display device shown in FIG. 3.

FIG. 5 is another equivalent circuit diagram of a temperature-sensing system in the display device shown in FIG. 3.

FIG. 6 is another diagram illustrating the structure of a display panel in a display device according to an embodiment of the present application.

FIG. 7 is an equivalent circuit diagram of a temperature-sensing system in the display device shown in FIG. 6.

FIG. 8 is a cross-sectional view taken along AA′ of the display device shown in FIG. 2.

FIG. 9 is a top view of a dashed box B in the display device shown in FIG. 2.

FIG. 10 is a diagram illustrating the partial circuit structure of the display device shown in FIG. 2.

FIG. 11 is a driving timing diagram of a display device according to an embodiment of the present application.

FIG. 12 is another driving timing diagram of a display device according to an embodiment of the present application.

### DETAILED DESCRIPTION

The present application is further described in detail below in conjunction with the drawings and embodiments. It is to be understood that the embodiments described herein are intended to illustrate the present application and not to limit the present application. In addition, it is to be noted that for ease of description, only part, not all, of structures related to the present application are illustrated in the drawings.

Terms used in the embodiments of the present application are used to describe the specific embodiments and not intended to limit the present application. It is to be noted that nouns of locality, including “up”, “down”, “left”, and “right” used in the embodiments of the present application, are described from the perspective of the drawings and are not to be construed as a limitation to the embodiments of the present application. In addition, in the context, it is to be understood that when a component is formed “on” or “below” another component, the component may not only be directly formed “on” or “below” another component and may also be indirectly formed “on” or “below” another component via an intermediate component. Terms such as “first” and “second” are used only for the purpose of description to distinguish between different components and not to indicate any order, quantity, or importance. For those of ordinary skill in the art, specific meanings of the preceding terms in the present application may be understood based on specific situations.

The terms “comprise”, “include”, and variations thereof in the present application are intended to be inclusive, that is, “including, but not limited to”. The term “based on” is “at least partially based on”. The term “an embodiment” refers to “at least one embodiment”.

It is to be noted that the terms such as “first” and “second” used in the present application are intended to distinguish corresponding contents and are not intended to limit any order or interdependency.

It is to be noted that “one” and “a plurality” mentioned in the present application are illustrative and not limiting and that those skilled in the art should understand that “one” and “a plurality” should be understood as “one or more” unless otherwise specified.

Using a vehicle-mounted display panel as an example, a temperature monitoring solution for an existing display panel is described below. First, the operating temperature range of a vehicle-mounted display module is typically from −40° C. to 85° C. Under high-temperature conditions, in order to prevent the display panel from failing due to the excessively high temperature of the display module, power reduction is required for the module, that is, when the temperature is relatively high, the display power of the display panel is appropriately reduced to decrease heat generation. For a liquid crystal display module, heat generation is typically concentrated in backlight light bars and driver integrated circuits (ICs). Therefore, thermistors are generally disposed near the backlight light bars and the driver ICs to accurately monitor the temperature.

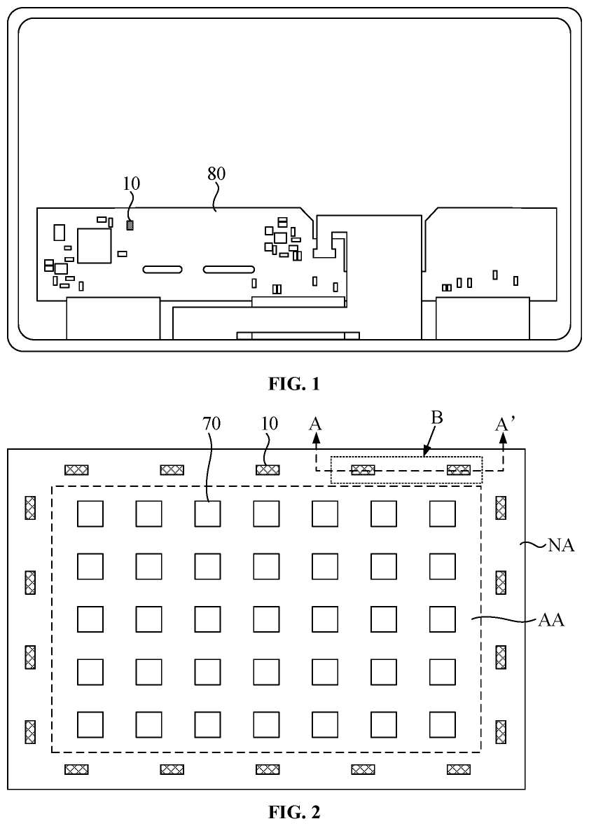

However, for a vehicle-mounted organic light-emitting diode (OLED) display module, the primary heat sources are OLED devices, a printed circuit board (PCB), and chip on film (COF). Due to their combined effect, high-temperature regions on the front side of the display module are not fixed and vary depending on the layout of the driver ICs. FIG. 1 is a diagram illustrating the rear structure of a vehicle-mounted OLED display module in the related art. Referring to FIG. 1, in the vehicle-mounted OLED display module, a temperature-sensing device 10, such as a temperature sensor or a thermistor, is typically mounted onto a PCB 80 and folded back with the PCB 80 onto the rear side of a display panel for temperature monitoring. Since the temperature-sensing device 10 is separated from the display panel by multiple layers, such as the PCB 80, adhesive auxiliary materials, and an aluminum plate, the temperature-sensing device 10 can only monitor local temperature values on the rear side of the display panel. It is difficult for the temperature-sensing device 10 to monitor the temperature distribution across the entire front surface of the display panel, thereby reducing the accuracy of temperature detection on the surface of the display panel, affecting overheat protection, and easily causing thermal damage to the display panel.

Regarding the preceding technical problems, embodiments of the present application provide a display device. FIG. 2 is a diagram illustrating the structure of a display panel in a display device according to an embodiment of the present application. Referring to FIG. 2, the display device includes a display panel and a main controller (not shown in FIG. 2). The display panel includes a display region AA, a non-display region NA connected to the display region AA, and multiple temperature-sensing devices 10. A temperature-sensing device 10 includes a PN junction. The multiple temperature-sensing devices 10 are located at different positions of the non-display region NA. The main controller is connected to the multiple temperature-sensing devices 10 and is configured to sequentially acquire forward voltage drops across PN junctions of the temperature-sensing devices 10 under a preset conduction current and determine, according to the forward voltage drops, temperatures at the different positions of the non-display region NA where the temperature-sensing devices 10 are located.

The display panel is divided into the display region AA and the non-display region NA. Those skilled in the art can understand that light-emitting devices 70 are provided and are disposed in the display region AA. By enabling the light-emitting devices 70 to emit light with specific colors, the colors can be mixed to fulfill the image display function. Driving circuits are typically provided and are disposed in the non-display region NA for driving the light-emitting devices 70 to emit light. In the embodiments of the present application, the temperature-sensing devices 10 are disposed at the different positions of the non-display region NA. In this manner, the temperature distribution of the display panel can be detected from the different positions of the non-display region NA so that heat generation during operation of the display panel can be accurately monitored, thereby enabling precise overheat regulation. In addition, occupying space in the display region can be avoided, thereby preventing an adverse impact on the resolution of the display region.

In the embodiments of the present application, the temperature-sensing device 10 is provided with the PN junction, and temperature detection is essentially performed by utilizing the electrical characteristics of the PN junction. In an embodiment, under a constant current bias, the forward voltage drop of the PN junction decreases approximately linearly with an increase in temperature. The electrical characteristic formula can be approximately expressed as: VBE(T)=VBE(T0)+k×(T−T0), where VBE(T) denotes the forward voltage drop of the PN junction at temperature T, VBE(T0) denotes the initial forward voltage drop of the PN junction at an initial temperature T0, and k≈−2 m V/° C. The underlying physical reason for the preceding electrical characteristic is that the intrinsic carrier concentration ni of semiconductor materials increases exponentially with temperature. As a result, under the same current, a junction voltage VBE required to sustain the same current decreases. It can be seen that, under the condition that the initial temperature T0 and the initial forward voltage drop VBE(T0) at the initial temperature T0 are known, the temperature T at the current position at which the PN junction is located can be calculated by detecting the actual forward voltage drop VBE(T) of the PN junction, thereby performing temperature detection. The initial temperature T0 and the initial forward voltage drop VBE(T0) need to be calibrated in advance. The initial temperature T0 can be understood as a preset temperature value. Under this preset temperature value, the voltage difference across the PN junction can be calibrated to obtain a determined forward voltage drop, which is defined as the initial forward voltage drop. Based on these two calibration parameters, the temperature difference T−T0 between the temperature T at the current position at which the PN junction is located and the initial temperature T0 can be calculated according to the actually detected voltage difference across the PN junction, that is, the actual forward voltage drop VBE(T), so the temperature T at the current position at which the PN junction is located can be obtained.

In addition, it is to be noted that, in the embodiments of the present application, the multiple temperature-sensing devices 10 are disposed at the different positions of the non-display region NA, so as to detect temperatures at different positions of the display panel. This can facilitate precise regulation and control of temperature abnormalities, such as overheating, at the different positions of the display panel. As illustrated in FIG. 2, optionally, the temperature-sensing devices 10 are uniformly disposed in the non-display region NA. On the basis of providing the multiple temperature-sensing devices 10, in the present application, the main controller sequentially supplies the preset conduction current to the PN junctions and sequentially detects the forward voltage drops across the PN junctions. Accordingly, temperatures at the positions at which the PN junctions are located can be calculated, thereby monitoring the temperatures at the different positions of the non-display region NA where the temperature-sensing devices 10 are located. It is to be further noted that the main controller may be understood as an external control unit of the display panel. The main controller may be connected to the display panel via connection lines and thereby connected to the temperature-sensing devices 10 disposed on the display panel, so as to fulfill the temperature detection function.

According to the preceding technical solutions, the multiple temperature-sensing devices are disposed in the non-display region of the display panel, are located at the different positions of the non-display region, and are connected to the main controller. The main controller sequentially acquires the forward voltage drops across the PN junctions of the temperature-sensing devices under the preset conduction current and determines, according to the forward voltage drops, the temperatures at the different positions of the non-display region where the temperature-sensing devices are located. In this manner, the temperatures at the various positions of the non-display region of the display panel can be monitored, thereby avoiding the problem of low temperature detection accuracy caused by the temperature-sensing devices being located far from heat sources. Moreover, by directly integrating the multiple temperature-sensing devices within the display panel, the temperatures at the different positions of the display panel can be effectively and accurately detected, thereby monitoring the temperature distribution across the entire front surface of the display panel. This can improve temperature detection accuracy of the display panel, facilitate power reduction when the temperature is excessively high, achieve overheat protection, prevent thermal damage to the display panel, and ensure the reliability and service life of the display panel.

In a specific embodiment, optionally, the temperature-sensing device 10 includes a diode and a bipolar junction transistor.

For the diode, which includes one PN junction, when detecting the voltage across the PN junction, the main controller may detect the voltage difference between a positive electrode and a negative electrode. For the bipolar junction transistor, that is, a BJT, the bipolar junction transistor essentially is composed of two back-to-back PN junctions and includes an emitter, a base, and a collector. When detecting the voltage across the PN junction, the main controller can detect the voltage difference between the base and the emitter.

In a specific embodiment, optionally, the ion doping concentration C of a P-type doped region 4011 and an N-type doped region 4012 in the PN junction satisfies that C≥1×10¹⁸ cm⁻³.

In this embodiment, the ion doping concentration of the doped regions in the PN junction is limited to improve the sensitivity of temperature detection. In an embodiment, for a highly doped PN junction, under the same temperature variation, the change in the voltage difference is more pronounced, that is, the sensitivity is higher, enabling more accurate detection and acquisition of the temperature at the position at which the highly doped PN junction is located. Using the bipolar junction transistor as an example, the voltage difference between the base and the emitter is that VBE=(kT/q)×ln(I_F/Is), where T denotes the temperature, k/q denotes a constant (approximately 86 μV/K), I_F denotes the preset conduction current, and Is denotes a reverse saturation current. A higher ion doping concentration of the doped regions in the PN junction corresponds to a larger Is. Under the same preset conduction current I_F, the term ln(I_F/I_s) decreases according to the preceding formula, thereby reducing the value of VBE. According to the temperature coefficient formula:,

$$\partial V BE / \partial T = [ V BE ( T ) - V G 0 ] / T - ( γ \times k ) / q ’$$

where VG0 denotes the bandgap voltage of silicon, with the magnitude of approximately 1.17 V, and γ denotes a constant related to parameters such as a temperature coefficient of carrier mobility, typically ranging from 3 to 4, when the initial VBE decreases while VG0=1.17 V remains unchanged, it can be seen from the temperature coefficient formula that the term [VBE(T)−VG0] becomes more negative, and thus [VBE(T)−VG0]/T also becomes more negative. As a result, the overall temperature coefficient ∂VBE/∂T shifts in a more negative direction, and its absolute value |∂VBE/∂T| increases, thereby achieving higher temperature-sensing sensitivity. In the embodiments of the present application, by limiting the ion doping concentration C to be no less than C≥1×10¹⁸ cm⁻³, a temperature conversion coefficient of about −2 mV/° C. or even higher can be obtained, enabling high-precision temperature detection of ±0.3° C. This can help improve the signal-to-noise ratio and accuracy of subsequent detection circuits. Compared with conventional thermistors, the temperature detection accuracy can be improved by more than 50%.

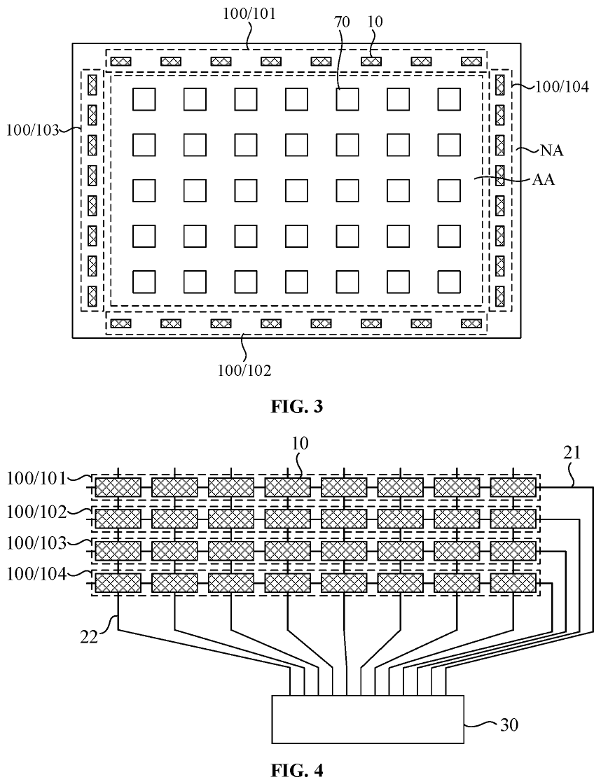

FIG. 3 is another diagram illustrating the structure of a display panel in a display device according to an embodiment of the present application. FIG. 4 is an equivalent circuit diagram of a temperature-sensing system in the display device shown in FIG. 3. Referring to FIGS. 3 and 4, optionally, the multiple temperature-sensing devices 10 include multiple temperature-sensing device groups 100, and the multiple temperature-sensing device groups 100 each include the same number of temperature-sensing devices 10.

The display panel further includes multiple gating lines 21 and multiple reading lines 22. The number of gating lines 21 is equal to the number of temperature-sensing device groups 100, and the number of reading lines 22 is equal to the number of temperature-sensing devices 10 in one temperature-sensing device group 100. A gating line 21 is connected to the temperature-sensing devices 10 in the temperature-sensing device group 100 and is connected to first electrodes of the temperature-sensing devices 10, and different gating lines 21 are connected to different temperature-sensing device groups 100. A reading line 22 is connected to one temperature-sensing device 10 in each temperature-sensing device group 100 and is connected to a second electrode of the temperature-sensing device 10, and different reading lines 22 are connected to different temperature-sensing devices 10 in the temperature-sensing device group 100.

The main controller 30 is connected to the gating lines 21 and the reading lines 22 and is configured to supply the preset conduction current to the gating lines 21 and determine the forward voltage drops according to the voltage differences between the gating lines 21 and the reading lines 22.

Those skilled in the art can understand that, due to the limited space of the display panel, the area of the non-display region NA determines the bezel size of the display device. When signal wires are provided in the non-display region NA to connect the temperature-sensing devices 10 to the main controller 30, an excessive number of signal wires significantly increases the area of the non-display region NA. To solve this problem, in this embodiment, the temperature-sensing devices 10 disposed in the non-display region NA are divided into the multiple temperature-sensing device groups 100 according to their positions. The temperature-sensing devices 10 in the multiple temperature-sensing device groups 100 are sequentially addressed and scanned via the gating lines 21 and the reading lines 22, so as to acquire the detection voltages of the temperature-sensing devices 10. In an embodiment, referring to FIG. 3, optionally, multiple temperature-sensing devices 10 located in vicinity within the non-display region NA are grouped into one temperature-sensing device group 100. First electrodes of the multiple temperature-sensing devices 10 located in vicinity are connected to one gating line 21, while second electrodes of the multiple temperature-sensing devices 10 are connected to different reading lines 22 in one-to-one correspondence. The gating line 21 supplies a fixed current, that is, the preset conduction current, to the temperature-sensing devices 10 of the temperature-sensing device group 100. The voltages on the reading lines 22 are sequentially read and subtracted from the voltage of the gating line 21, thereby obtaining the voltage difference across the two terminals of each temperature-sensing device 10 in the temperature-sensing device group 100, that is, VBE(T). Further, according to the preceding conversion formula VBE(T)=VBE(T0)+k×(T−T0) and the pre-calibrated parameters VBE(T0) and T0, the actual temperature T at the current position can be calculated. It is to be understood that the number of temperature-sensing device groups 100 into which the temperature-sensing devices 10 disposed in the non-display region (NA) are divided is the number of gating lines 21 to be provided, and the number of temperature-sensing devices 10 in the temperature-sensing device group 100 is the number of reading lines 22 to be provided. Accordingly, the signal wires between the temperature-sensing devices 10 and the main controller 30 can be significantly reduced. While the actual temperatures at the positions at which the temperature-sensing devices 10 are located are effectively read, the area of the non-display region of the display panel is saved, thereby reducing the layout burden of integrating the temperature-sensing system on the display panel in the non-display region to a certain extent.

It is to be noted that when the temperature-sensing devices are diodes, the first electrodes of the temperature-sensing devices that are connected to the gating line 21 may be positive electrodes, and the second electrodes of the temperature-sensing devices that are connected to the reading lines 22 may be negative electrodes. When the temperature-sensing devices are bipolar junction transistors, the first electrodes of the temperature-sensing devices that are connected to the gating line 21 may be bases, and the second electrodes of the temperature-sensing devices that are connected to the reading lines 22 may be emitters. Certainly, those skilled in the art may also optionally adopt a connection manner opposite to the preceding example according to actual requirements, and the present application is not limited thereto.

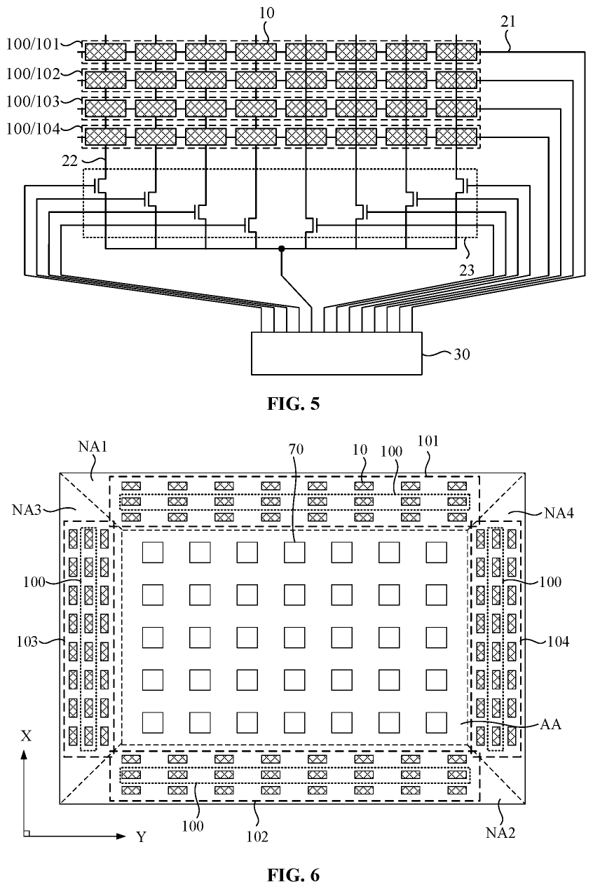

FIG. 5 is another equivalent circuit diagram of a temperature-sensing system in the display device shown in FIG. 3. Referring to FIGS. 3 and 5, optionally, the display panel further includes at least one multiplexer 23. A multiplexer 23 includes multiple input terminals and one output terminal. Input terminals of the at least one multiplexer 23 are connected to the reading lines 22 in one-to-one correspondence, and an output terminal of the at least one multiplexer 23 is connected to the main controller 30.

The main controller 30 is configured to, when the multiple input terminals of the multiplexer 23 are sequentially gated to the output terminal of the multiplexer 23, correspondingly acquire a voltage difference between a target gating line 21 and a target reading line 22 and determine a forward voltage drop across a PN junction of a target temperature-sensing device 10 under the preset conduction current, where the target gating line 21 is a gating line 21 that receives the preset conduction current supplied by the main controller 30, the target reading line 22 is a reading line 22 that is connected to an input terminal that is gated to the output terminal, and the target temperature-sensing device 10 is a temperature-sensing device 10 that is connected to the target gating line 21 and the target reading line 22.

In this embodiment, by providing the multiplexer 23, any channel of the multiplexer 23 can be controlled and gated through a gating control signal. For example, when a first channel of the multiplexer 23 is controlled to be turned on so that a first reading line 22 is connected to the main controller 30, the main controller 30 sequentially supplies the preset conduction current to the gating lines 21 and can sequentially acquire the voltages on the first reading line synchronously, that is, the voltage of a temperature-sensing device 10 in each temperature-sensing device group 100 connected to the first reading line. In this manner, the temperature-sensing device 10 in each temperature-sensing device group 100 connected to the first reading line can be addressed and scanned. Similarly, when various channels of the multiplexer 23 are controlled to be turned on so that the reading lines are connected to the main controller 30, the main controller 30 can also sequentially supply the preset conduction current to the gating lines 21 and sequentially acquire the voltages of the temperature-sensing devices 10 in the temperature-sensing device groups 100 on the multiple currently turned-on reading lines synchronously. In this manner, all the temperature-sensing devices 10 can be addressed and scanned, and temperature data at the positions at which the temperature-sensing devices 10 are located can be obtained.

It is to be noted that only one multiplexer 23 is illustrated as an example in FIG. 5. Those skilled in the art may provide multiple multiplexers according to actual requirements, for example, when there are a large number of temperature-sensing device groups or temperature-sensing devices, so as to address and scan the temperature-sensing devices. As illustrated in FIG. 5, one temperature-sensing device group 100 is disposed in each of upper, lower, left, and right regions of the non-display region NA. Those skilled in the art may also optionally provide multiple temperature-sensing device groups in each of the four regions and provide one multiplexer for the temperature-sensing device groups in the same region to perform scanning and addressing, which is not limited herein. In addition, the equivalent circuit diagrams shown in FIGS. 4 and 5 illustrate connection relationships only for explaining the addressing and scanning solution employed by the main controller for the temperature-sensing devices in the temperature-sensing device groups. The size, positional relationship, and arrangement of components such as devices, wires, and the main controller are not intended to be limiting or used as a reference.

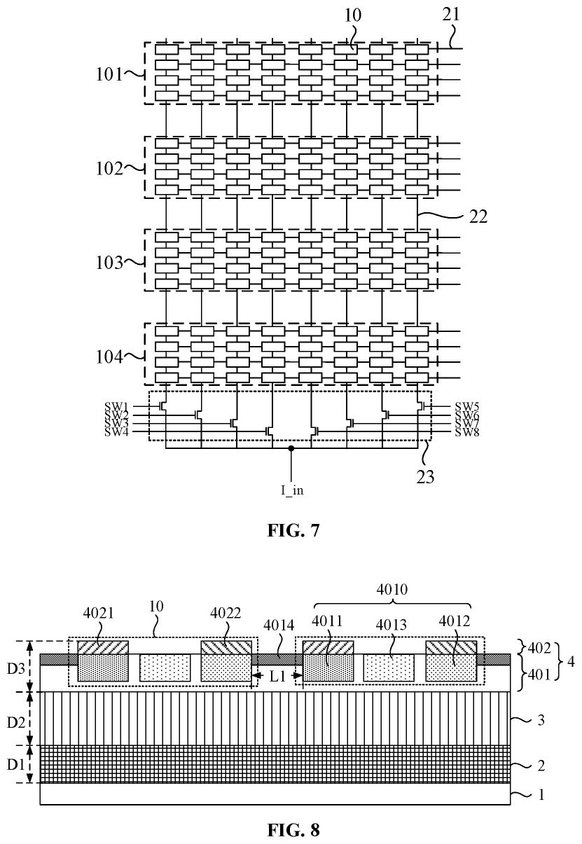

FIG. 6 is another diagram illustrating the structure of a display panel in a display device according to an embodiment of the present application. FIG. 7 is an equivalent circuit diagram of a temperature-sensing system in the display device shown in FIG. 6. Referring to FIGS. 3, 6, and 7, optionally, the non-display region NA includes a first sub-region NA1, a second sub-region NA2, a third sub-region NA3, and a fourth sub-region NA4. The first sub-region NA1 and the second sub-region NA2 are respectively located on two sides of the display region AA that face away from each other in the first direction X, and the third sub-region NA3 and the fourth sub-region NA4 are respectively located on two sides of the display region AA that face away from each other in the second direction Y. The first direction X intersects the second direction Y.

The multiple temperature-sensing devices 10 include a first temperature-sensing device array 101, a second temperature-sensing device array 102, a third temperature-sensing device array 103, and a fourth temperature-sensing device array 104. The first temperature-sensing device array 101 is located in the first sub-region NA1, the second temperature-sensing device array 102 is located in the second sub-region NA2, the third temperature-sensing device array 103 is located in the third sub-region NA3, and the fourth temperature-sensing device array 104 is located in the fourth sub-region NA4. Temperature-sensing devices 10 in the first temperature-sensing device array 101 and the second temperature-sensing device array 102 are arranged in an M×N array along the first direction X and the second direction Y. Temperature-sensing devices 10 in the third temperature-sensing device array 103 and the fourth temperature-sensing device array 104 are arranged in an N×M array along the first direction X and the second direction Y. M and N are positive integers.

The first sub-region NA1 and the second sub-region NA2 may be understood as an upper non-display region and a lower non-display region, respectively, and the third sub-region NA3 and the fourth sub-region NA4 may be understood as a left non-display region and a right non-display region, respectively. The temperature-sensing devices 10 located in the first sub-region NA1 and the second sub-region NA2 and the temperature-sensing devices 10 located in the third sub-region NA3 and the fourth sub-region NA4 may be arranged in arrays, respectively, thereby forming the first temperature-sensing device array 101, the second temperature-sensing device array 102, the third temperature-sensing device array 103, and the fourth temperature-sensing device array 104. Furthermore, considering that the upper non-display region and the lower non-display region extend in the left-right direction, while the left non-display region and the right non-display region extend in the up-down direction, the temperature-sensing devices 10 may be arranged in an identical array in a manner of relative 90° rotation. In this manner, the four sub-regions of the non-display region can be ensured to have the same number of temperature-sensing devices 10 and a similar temperature-sensing layout. As illustrated in FIG. 3, the first temperature-sensing device array 101 and the second temperature-sensing device array 102 may be each arranged in a 1×8 array, where each row may be understood as one temperature-sensing device group 100; the third temperature-sensing device array 103 and the fourth temperature-sensing device array 104 may be each arranged in an 8×1 array, where each column may be understood as one temperature-sensing device group 100. As illustrated in FIGS. 6 and 7, the first temperature-sensing device array 101 and the second temperature-sensing device array 102 may be each arranged in a 4×8 array, where each row may be similarly understood as one temperature-sensing device group 100; the third temperature-sensing device array 103 and the fourth temperature-sensing device array 104 may be each arranged in an 8×4 array, where each column may also be understood as one temperature-sensing device group 100.

It is to be noted that the arrangement manner of the preceding four temperature-sensing device arrays is an example, and the number of rows and columns in each array within each sub-region is not limited in this embodiment. In a specific embodiment, optionally, the number of temperature-sensing devices is not greater than 128. As illustrated in FIGS. 6 and 7, 32 temperature-sensing devices are provided in each of the four sub-regions, forming a 16×8 two-dimensional array with a total of 128 temperature-sensing devices. Since 128 temperature-sensing detection points can form a sufficiently dense temperature-sensing detection network on the display panel, the density is already adequate to accurately capture local hot spots and overall temperature gradient variations. Further increasing the number of temperature-sensing detection points would provide only very limited improvement in the detection accuracy of the overall temperature-sensing system. Moreover, since each temperature-sensing device needs to be connected to a reading circuit via a signal line, the 128 temperature-sensing detection points already require considerably complex internal wiring. If the number of temperature-sensing detection points is increased to, for example, 256, the wiring density would increase sharply, occupying more valuable space of the display panel.

FIG. 8 is a cross-sectional view taken along AA′ of the display device shown in FIG. 2. Referring to FIGS. 2 and 8, optionally, the display panel further includes a substrate base 1, a driving circuit layer 2, an insulating layer 3, and a temperature-sensing device layer 4. In a direction perpendicular to the substrate base 1 and facing away from the substrate base 1, the driving circuit layer 2, the insulating layer 3, and the temperature-sensing device layer 4 are sequentially stacked. The temperature-sensing devices 10 are formed in the temperature-sensing device layer 4.

The driving circuit layer 2 may be understood as a circuit structure layer in the display panel for driving the light-emitting devices 70 to emit light. It is known to those skilled in the art that, on the substrate base 1 of the display panel, pixel circuits need to be disposed in the display region AA, and gate scanning circuits need to be disposed in the non-display region NA. The gate scanning circuits are connected to the pixel circuits and can supply scanning signals to the pixel circuits, so as to control the pixel circuits to drive the correspondingly connected light-emitting devices 70 to emit light. Accordingly, the driving circuit layer 2 herein may include the circuit structure layer composed of the pixel circuits and the gate scanning circuits. On this basis, in the embodiments of the present application, the temperature-sensing device layer 4 is disposed on the driving circuit layer 2 in the non-display region NA to prepare and form the multiple temperature-sensing devices 10. It is to be understood that, in order to avoid mutual interference between the temperature-sensing devices 10 and the circuit structure for driving the light-emitting devices 70, the insulating layer 3 may be disposed between the temperature-sensing device layer 4 and the driving circuit layer 2 for insulation.

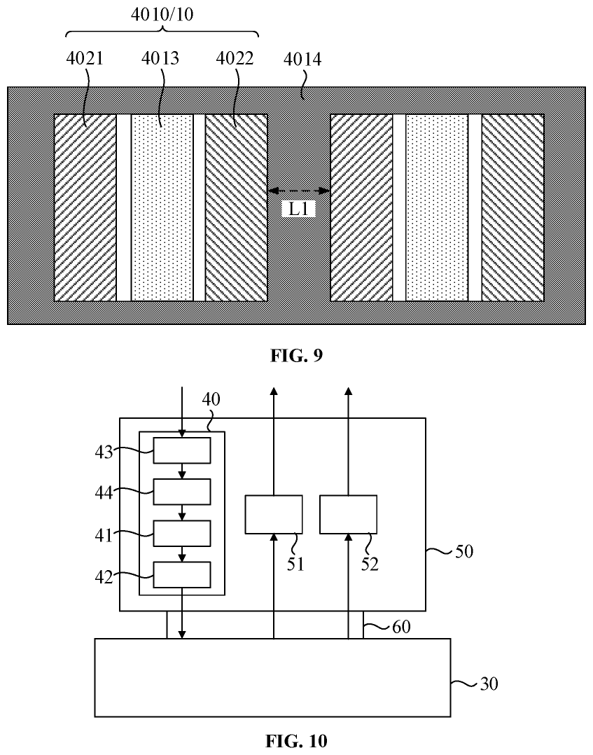

FIG. 9 is a top view of a dashed box B in the display device shown in FIG. 2. Referring to FIGS. 2, 8, and 9, further, the temperature-sensing device layer 4 may include a semiconductor layer 401 and an electrode layer 402. The semiconductor layer 401 includes multiple device regions 4010, and a device region 4010 includes an intrinsic isolation region 4013, a P-type doped region 4011, and an N-type doped region 4012. The P-type doped region 4011 and the N-type doped region 4012 are respectively located on two sides of the intrinsic isolation region 4013 that face away from each other in a direction parallel to the substrate base 1. The semiconductor layer 401 of the P-type doped region 4011 is doped with an acceptor dopant, and the semiconductor layer 401 of the N-type doped region 4012 is doped with a donor dopant. The semiconductor layer 401 of the intrinsic isolation region 4013, the semiconductor layer 401 of the P-type doped region 4011, and the semiconductor layer 401 of the N-type doped region 4012 form one temperature-sensing device 10. The electrode layer 402 includes anodes 4021 and cathodes 4022. An anode 4021 covers the surface of a side of the semiconductor layer 401 of the P-type doped region 4011 facing away from the driving circuit layer 2, and a cathode 4022 covers the surface of a side of the semiconductor layer 401 of the N-type doped region 4012 facing away from the driving circuit layer 2.

The structure of the preceding temperature-sensing device 10 is essentially a typical PIN junction, which can enable the temperature-sensing device 10 to exhibit the advantages of efficient carrier injection, fast switch response, and high breakdown voltage. In an embodiment, in the PIN junction, the P-type doped region 4011 injects holes into the intrinsic region under a forward bias voltage, and the N-type doped region 4012 injects electrons into the intrinsic region. The intrinsic isolation region, serving as a key region for carrier transport and recombination, accommodates and facilitates carrier recombination under the forward bias voltage and becomes fully depleted under a reverse bias voltage so as to withstand a high voltage and reduce a junction capacitor. The anode 4021 and the cathode 4022 are used for an electrical connection with an external circuit.

It is to be further noted that, optionally, after the preparation of the preceding PIN junction, an annealing process may be performed on the PIN junction. It is known to those skilled in the art that, after the preparation of the PIN junction, for example, when the P-type doped region 4011 and the N-type doped region 4012 are formed by ion injection, the lattice structure may be damaged, and injected impurity atoms may reside at electrically inactive interstitial positions. In this embodiment, by introducing the annealing process, on the one hand, the impurities can be activated, and high energy is provided within a short period of time to enable the impurity atoms to move to lattice sites and become electrically active atoms capable of providing carriers, thereby forming desirable PN junction characteristics; on the other hand, damage to silicon lattice caused during the ion injection can be repaired, thereby reducing defects and lowering a leakage current. In addition, the annealing process can also ensure that good ohmic contact is formed during subsequent metallization with PN junction electrodes, thereby reducing contact resistors. By employing rapid annealing, for example, at 450° C. for 30 s, problems related to thermal compatibility between organic materials and semiconductor devices can be solved, thereby achieving a balance between PN junction activation quality and protection of OLED organic layers.

With continued reference to FIGS. 3, 8, and 9, in an optional embodiment, the semiconductor layer 401 of the temperature-sensing device layer 4 may further include shallow trench isolation regions 4014. A shallow trench isolation region 4014 is located between adjacent device regions 4010 in the direction parallel to the substrate base 1.

The shallow trench isolation region 4014 is essentially a trench filled with an insulating medium, such as silicon dioxide. The shallow trench isolation region 4014 is disposed between adjacent PIN junctions, that is, between adjacent temperature-sensing devices 10, with the primary function to provide electrical isolation. In an embodiment, the shallow trench isolation region 4014 can physically block a potential parasitic conductive path between adjacent devices and effectively suppress leakage currents caused by surface states, thereby preventing leakage and signal crosstalk between the devices. Providing the shallow trench isolation regions 4014 for multiple independently operating temperature-sensing PIN junctions is critical for ensuring the independent operation of each device, improving a breakdown voltage, and reducing the overall static power consumption of a circuit.

With continued reference to FIGS. 3, 8, and 9, optionally, the thickness D1 of the driving circuit layer 2 ranges from 0.2 μm to 0.5 μm, and/or the thickness D2 of the insulating layer 3 ranges from 0.3 μm to 1.5 μm, and/or the thickness D3 of the semiconductor layer 401 ranges from 0.1 μm to 0.5 μm.

The thickness of the preceding insulating layer 3 ranges from 0.3 μm to 1.5 μm, which can ensure a sufficient thickness for the insulating layer to achieve effective isolation between the temperature-sensing devices 10 and the driving circuits of the display panel. The thickness of the preceding semiconductor layer 401 ranges from 0.1 μm to 0.5 μm, which can provide a sufficient thickness for the PIN junction to facilitate P-type and N-type ion doping. In addition, the preceding ranges also limit excessive thicknesses of the insulating layer 3 and the semiconductor layer 401, thereby preventing an increase in the overall thickness of the display panel.

With continued reference to FIGS. 3, 8, and 9, optionally, the size range of the device region 4010 is greater than or equal to 20 μm×20 μm, and the distance L1 between adjacent device regions 4010 is not less than 1 mm.

By employing a miniaturized design of 20 μm×20 μm or larger, the PIN junction can be sufficiently cooled back to the ambient temperature between two measurements, thereby reducing self-heating effects and preventing self-heating from affecting the temperature measurement accuracy of the temperature-sensing device 10. In this manner, a functionally robust PIN junction can be formed to carry a micro bias current required for measurement (such as tens of microamperes) and generate a measurable voltage signal with a sufficient signal-to-noise ratio.

FIG. 10 is a diagram illustrating the partial circuit structure of the display device shown in FIG. 2. In an embodiment, referring to FIGS. 2 and 10, the display panel further includes a front-end circuit 40. The front-end circuit 40 includes a differential amplifier circuit 41 and an analog-to-digital conversion circuit 42. The front-end circuit 40 is connected between the temperature-sensing device 10 and the main controller 30. The differential amplifier circuit 41 is connected across the PN junction of the temperature-sensing device 10 and is configured to amplify an acquired forward voltage across the PN junction and output the amplified forward signal. The analog-to-digital conversion circuit 42 is connected to the differential amplifier circuit 41 and is configured to convert the amplified forward voltage from an analog signal into a digital signal and supply the digital signal to the main controller 30.

The front-end circuit 40 may be understood as a front-end data processing circuit before computation by the main controller 30 and is configured to process a voltage signal fed back from the temperature-sensing device 10, so as to facilitate reading and conversion into temperature data by the main controller 30. As described in the preceding, the temperature-sensing devices 10 in the display panel can form the temperature-sensing device arrays that are addressed and scanned via the gating lines 21 and the reading lines 22. On this basis, the gating lines 21 and the reading lines 22 may be connected to the front-end circuit 40. Through the differential amplifier circuit 41 in the front-end circuit 40, weak differential signals on the gating lines 21 and the reading lines 22, that is, the acquired forward voltages across the PN junctions, can be amplified and converted into digital voltage signals through analog-to-digital conversion, and the digital voltage signals can be supplied to the main controller 30.

Further, optionally, the front-end circuit 40 further includes an electrostatic protection circuit 43 and a low-pass filter circuit 44. The electrostatic protection circuit 43 and the low-pass filter circuit 44 are sequentially connected between the temperature-sensing device 10 and the differential amplifier circuit 41.

In addition, to avoid interference from external static electricity and external electromagnetic signals, the embodiments of the present application may further provide the electrostatic protection circuit 43 and the low-pass filter circuit 44 in the front-end circuit 40. The electrostatic protection circuit 43 can discharge the static electricity generated on the display panel, and the low-pass filter circuit 44 can shield against interference from the external electromagnetic signals, thereby preventing the static electricity from damaging the main controller 30 and preventing the electromagnetic signals from interfering with the accuracy of temperature detection by the main controller 30.

Further, optionally, the display panel further includes a driver chip 50, and the front-end circuit 40 is integrated in the driver chip 50; the display device further includes an I²C bus, the temperature-sensing devices 10 are connected to the driver chip 50, and the driver chip 50 is connected to the main controller 30 via the I²C bus.

Further, optionally, the display panel further includes multiple light-emitting devices 70 located in the display region AA; the driver chip 50 is further integrated with a gate driving circuit 51 and a source driving circuit 52, and the light-emitting devices 70 are connected to the gate driving circuit 51 and the source driving circuit 52.

The front-end circuit 40, as a dedicated “analog front-end” module, is integrated in the driver chip 50 together with circuits required by the display panel such as the gate driving circuit, the source driving circuit, and a timing control circuit. This can significantly shorten the transmission distance of a voltage analog signal from the temperature-sensing device 10 on the display panel, thereby minimizing susceptibility to interference, ensuring the quality of a detection signal of the temperature-sensing device 10, and improving the accuracy of temperature detection. In addition, integrating the front-end circuit 40, the gate driving circuit 51, and the source driving circuit 52 in the driver chip 50 can enable high-level integration without requiring additional external chips, thereby saving space and cost and allowing the temperature-sensing system and the display function to share a power management unit for optimized power consumption control. In other words, by integrating the front-end circuit 40 in the driver chip 50, deep integration between temperature sensing and display is achieved at the physical and protocol levels, forming a truly intelligent display system rather than a simple stacked architecture. Optionally, the driver chip 50 may be disposed in the non-display region NA of the display panel or may be disposed on a flexible circuit board via the COF technology, which is not limited herein.

In addition, the I²C bus is a multi-master, half-duplex serial bus that inherently supports multiple devices. Including clock lines and data lines and featuring a robust protocol, the I²C bus is well suited for transmitting low-speed and small-volume control and sensing data such as temperature. In this embodiment, the driver chip 50 and the main controller 30 are configured to transmit data via the I²C bus, which can reuse the existing display control I²C bus for temperature data transmission, thereby avoiding the need for additional dedicated signal lines for the temperature-sensing devices, reducing the number of pins and wires of the main controller 30, and lowering cost, complexity, and failure rate.

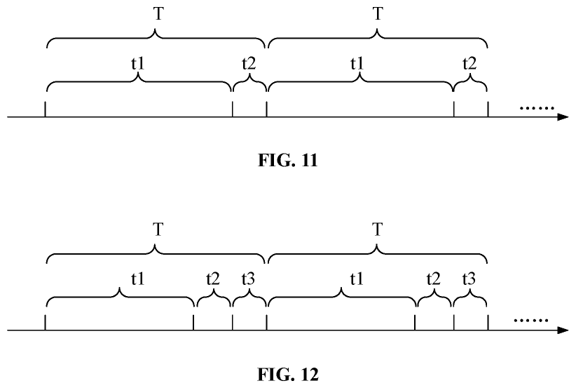

FIG. 11 is a driving timing diagram of a display device according to an embodiment of the present application. Referring to FIGS. 2 and 11, first, in the embodiment of the present application, the display panel further includes multiple light-emitting devices 70 that are located in the display region AA and are connected to the main controller. The driving process of the display device includes multiple display frames T, a display frame T includes a display stage t1 and a temperature-sensing stage t2, and the temperature-sensing stage t2 follows the display stage t1.

The main controller is further configured to: in the display stage t1, drive the light-emitting devices 70 to display according to a preset driving voltage corresponding to the current display frame T; and in the temperature-sensing stage t2, supply the preset conduction current to the temperature-sensing devices 10, acquire the forward voltage drops across the PN junctions of the temperature-sensing devices 10 under the preset conduction current, and determine, according to the forward voltage drops, the temperatures at the positions at which the temperature-sensing devices 10 are located.

First, the temperature-sensing stage t2 may be understood as performing temperature sensing during a vertical blanking period between two adjacent display stages t1. When the light-emitting devices 70 are driven for display, heat can be generated, thereby monitoring the different positions of the display panel in real time in the temperature-sensing stage t2. The driving process of the display panel provided in this embodiment is essentially a time-division multiplexing process of the main controller, which requires precise timing coordination among the driver chip 50 and the temperature-sensing devices 10. The time-division multiplexing process of the main controller is described below.

In the display stage t1, the main controller is responsible for driving the light-emitting devices 70 in the display region AA to emit light. The main controller may first supply display instructions and parameters, such as luminance data and gamma correction values, to the driver chip 50. The driver chip 50 generates pixel-level waveforms according to the instructions and parameters, and supplies the waveforms to the light-emitting devices 70 for display.

In the temperature-sensing stage t2, the main controller transmits a temperature sampling instruction to the temperature-sensing devices in the non-display region NA via the I²C bus, that is, supplies the preset conduction current to the temperature-sensing devices. Subsequently, the 128 temperature-sensing devices 10 transmit a data packet including 128 nodes×2 bytes via the I²C bus, so as to sequentially perform addressing scanning, differential amplification, analog-to-digital conversion, and temperature calculation, thereby acquiring the current temperature data of the temperature-sensing devices 10.

FIG. 12 is another driving timing diagram of a display device according to an embodiment of the present application. Referring to FIGS. 2 and 12, in another embodiment of the present application, a compensation calculation stage t3 may also be provided in the display frame T and follows the temperature-sensing stage t2. The main controller is further configured to: in the compensation calculation stage t3, correct preset driving voltages corresponding to light-emitting devices 70 adjacent to the temperature-sensing devices 10 in the next display frame T according to the temperatures at the positions at which the temperature-sensing devices 10 are located.

The compensation calculation stage t3 is also disposed within the vertical blanking period between two adjacent display stages t1 or may be understood as occurring before the next display stage t1. The compensation calculation stage t3 is mainly a process of feedback regulation of the display of the light-emitting devices 70 at corresponding positions based on the temperature data acquired at the different positions of the display panel in the temperature-sensing stage t2. It is to be understood by those skilled in the art that, in the display stage t1, since different display frames T correspond to different display images, specific preset driving voltages need to be supplied to the light-emitting devices 70 so that the light-emitting devices 70 emit light at preset brightness levels to form a desired display image. In this embodiment, based on the temperature data at the different positions of the display panel that is detected in the temperature-sensing stage t2, the preset driving voltage of the next display stage t1 can be corrected, thereby feedback-regulating heat generation of light-emitting devices 70 in corresponding regions and controlling the temperatures of those regions of the display panel within a standard temperature range. In an embodiment, a pulse width modulation (PWM) compensation algorithm may be executed according to the temperature at the position at which the temperature-sensing device 10 is located, so as to adjust the duty cycle of an effective pulse of the driving voltage and control the flicker frequency of the light-emitting device 70. In this manner, when local overheating occurs in the display panel, the pulse width of the driving voltage can be reduced, thereby lowering the flicker frequency of the light-emitting device 70 and preventing continuous light emission and heat accumulation of the light-emitting device 70. As a result, the local temperature can be stabilized, heat protection of the display panel can be achieved, and the service life of the display panel can be prolonged.

It is to be noted that the preceding are preferred embodiments of the present application and technical principles used therein. It is to be understood by those skilled in the art that the present application is not limited to the embodiments described herein. Those skilled in the art can make various apparent modifications, adaptations, combinations, and substitutions without departing from the scope of the present application. Therefore, while the present application is described in detail through the preceding embodiments, the present application is not limited to the preceding embodiments and may include other equivalent embodiments without departing from the concept of the present application. The scope of the present application is determined by the scope of the appended claims.

What is claimed is:

1. A display device, comprising a display panel and a main controller,
wherein the display panel comprises a display region and a non-display region connected to the display region and further comprises a plurality of temperature-sensing devices, a temperature-sensing device of the plurality of temperature-sensing devices comprises a PN junction, and the plurality of temperature-sensing devices are located at different positions of the non-display region; and
wherein the main controller is connected to the plurality of temperature-sensing devices, and the main controller is configured to sequentially acquire forward voltage drops across PN junctions of the plurality of temperature-sensing devices under a preset conduction current and determine, according to the forward voltage drops, temperatures at the different positions of the non-display region where the plurality of temperature-sensing devices are located.

2. The display device according to claim 1, wherein the plurality of temperature-sensing devices comprise a plurality of temperature-sensing device groups, and the plurality of temperature-sensing device groups each comprises a same number of temperature-sensing devices;
the display panel further comprises a plurality of gating lines and a plurality of reading lines, a number of gating lines is equal to a number of temperature-sensing device groups, and a number of reading lines is equal to a number of temperature-sensing devices in one temperature-sensing device group of the plurality of temperature-sensing device groups;
a gating line of the plurality of gating lines is connected to the temperature-sensing devices in the temperature-sensing device group and is connected to first electrodes of the temperature-sensing devices, and different gating lines of the plurality of gating lines are connected to different temperature-sensing device groups of the plurality of temperature-sensing device groups;
a reading line of the plurality of reading lines is connected to one temperature-sensing device in each temperature-sensing device group of the plurality of temperature-sensing device groups and is connected to a second electrode of the temperature-sensing device, and different reading lines of the plurality of reading lines are connected to different temperature-sensing devices in the each temperature-sensing device group; and
the main controller is connected to the plurality of gating lines and the plurality of reading lines and is configured to sequentially supply the preset conduction current to the plurality of gating lines and determine the forward voltage drops according to voltage differences between the plurality of gating lines and the plurality of reading lines.

3. The display device according to claim 2, wherein the display panel further comprises at least one multiplexer, and a multiplexer of the at least one multiplexer comprises a plurality of input terminals and one output terminal;
input terminals of the at least one multiplexer are connected to the plurality of reading lines in one-to-one correspondence, and an output terminal of the at least one multiplexer is connected to the main controller; and
the main controller is configured to, when the plurality of input terminals of the multiplexer are sequentially gated to the output terminal of the multiplexer, correspondingly acquire a voltage difference between a target gating line and a target reading line and determine a forward voltage drop across a PN junction of a target temperature-sensing device under the preset conduction current, wherein the target gating line is a gating line of the plurality of gating lines that receives the preset conduction current supplied by the main controller, the target reading line is a reading line of the plurality of reading lines that is connected to an input terminal of the plurality of input terminals that is gated to the output terminal, and the target temperature-sensing device is a temperature-sensing device of the plurality of temperature-sensing devices that is connected to the target gating line and the target reading line.

4. The display device according to claim 1, wherein the non-display region comprises a first sub-region, a second sub-region, a third sub-region, and a fourth sub-region;
the first sub-region and the second sub-region are respectively located on two sides of the display region that face away from each other in a first direction, and the third sub-region and the fourth sub-region are respectively located on two sides of the display region that face away from each other in a second direction, wherein the first direction intersects the second direction;
the plurality of temperature-sensing devices comprise a first temperature-sensing device array, a second temperature-sensing device array, a third temperature-sensing device array, and a fourth temperature-sensing device array; the first temperature-sensing device array is located in the first sub-region, the second temperature-sensing device array is located in the second sub-region, the third temperature-sensing device array is located in the third sub-region, and the fourth temperature-sensing device array is located in the fourth sub-region;
temperature-sensing devices in the first temperature-sensing device array and the second temperature-sensing device array are arranged in an M ×N array along the first direction and the second direction; and
temperature-sensing devices in the third temperature-sensing device array and the fourth temperature-sensing device array are arranged in an N ×M array along the first direction and the second direction,
wherein M and N are positive integers.

5. The display device according to claim 4, wherein a number of temperature-sensing devices is not greater than 128.

6. The display device according to claim 1, wherein the temperature-sensing device comprises a diode and a bipolar junction transistor.

7. The display device according to claim 1, wherein an ion doping concentration C of a P-type doped region and an N-type doped region in the PN junction satisfies that C≥1×10¹⁸ cm⁻³.

8. The display device according to claim 1, wherein the display panel further comprises a substrate base, a driving circuit layer, an insulating layer, and a temperature-sensing device layer; and
in a direction perpendicular to the substrate base and facing away from the substrate base, the driving circuit layer, the insulating layer, and the temperature-sensing device layer are sequentially stacked, and the plurality of temperature-sensing devices are formed in the temperature-sensing device layer.

9. The display device according to claim 8, wherein the temperature-sensing device layer comprises a semiconductor layer and an electrode layer;
the semiconductor layer comprises a plurality of device regions, and a device region of the plurality of device regions comprises an intrinsic isolation region, a P-type doped region, and an N-type doped region; the P-type doped region and the N-type doped region are respectively located on two sides of the intrinsic isolation region that face away from each other in a direction parallel to the substrate base; the semiconductor layer of the P-type doped region is doped with an acceptor dopant, and the semiconductor layer of the N-type doped region is doped with a donor dopant; the semiconductor layer of the intrinsic isolation region, the semiconductor layer of the P-type doped region, and the semiconductor layer of the N-type doped region form a temperature-sensing device of the plurality of temperature-sensing devices; and
the electrode layer comprises anodes and cathodes, an anode of the anodes covers a surface of a side of the semiconductor layer of the P-type doped region facing away from the driving circuit layer, and a cathode of the cathodes covers a surface of a side of the semiconductor layer of the N-type doped region facing away from the driving circuit layer.

10. The display device according to claim 9, wherein the semiconductor layer further comprises a shallow trench isolation region, and the shallow trench isolation region is located between adjacent device regions of the plurality of device regions in the direction parallel to the substrate base.

11. The display device according to claim 9, wherein at least one of the following is satisfied:
a thickness of the driving circuit layer ranges from 0.2 μm to 0.5 μm;
a thickness of the insulating layer ranges from 0.3 μm to 1.5 μm; or
a thickness of the semiconductor layer ranges from 0.1 μm to 0.5 μm.

12. The display device according to claim 9, wherein a size range of the device region is greater than or equal to 20 μm×20 μm, and a distance between adjacent device regions of the plurality of device regions is not less than 1 mm.

13. The display device according to claim 1, wherein the display panel further comprises a front-end circuit, the front-end circuit comprises a differential amplifier circuit and an analog-to-digital conversion circuit, and the front-end circuit is connected between the temperature-sensing device and the main controller;
the differential amplifier circuit is connected across the PN junction of the temperature-sensing device and is configured to amplify an acquired forward voltage across the PN junction and output the amplified forward voltage; and
the analog-to-digital conversion circuit is connected to the differential amplifier circuit and is configured to convert the amplified forward voltage from an analog signal into a digital signal and supply the digital signal to the main controller.

14. The display device according to claim 13, wherein the front-end circuit further comprises an electrostatic protection circuit and a low-pass filter circuit; and
the electrostatic protection circuit and the low-pass filter circuit are sequentially connected between the temperature-sensing device and the differential amplifier circuit.

15. The display device according to claim 13, wherein the display panel further comprises a driver chip, and the front-end circuit is integrated in the driver chip; and
the display device further comprises an I²C bus, the plurality of temperature-sensing devices are connected to the driver chip, and the driver chip is connected to the main controller via the I²C bus.

16. The display device according to claim 15, wherein the display panel further comprises a plurality of light-emitting devices, and the plurality of light-emitting devices are located in the display region; and
the driver chip is further integrated with a gate driving circuit and a source driving circuit, and the plurality of light-emitting devices are connected to the gate driving circuit and the source driving circuit.

17. The display device according to claim 1, wherein the display panel further comprises a plurality of light-emitting devices, and the plurality of light-emitting devices are located in the display region and are connected to the main controller;
a driving process of the display device comprises a plurality of display frames, a display frame of the plurality of display frames comprises a display stage and a temperature-sensing stage, and the temperature-sensing stage follows the display stage; and
the main controller is further configured to:
in the display stage, drive the plurality of light-emitting devices to display according to a preset driving voltage corresponding to a current display frame of the plurality of display frames; and
in the temperature-sensing stage, supply the preset conduction current to the plurality of temperature-sensing devices, acquire the forward voltage drops across the PN junctions of the plurality of temperature-sensing devices under the preset conduction current, and determine, according to the forward voltage drops, the temperatures at the positions at which the plurality of temperature-sensing devices are located.

18. The display device according to claim 17, wherein the display frame further comprises a compensation calculation stage, and the compensation calculation stage follows the temperature-sensing stage; and
the main controller is further configured to:
in the compensation calculation stage, correct preset driving voltages corresponding to light-emitting devices adjacent to the temperature-sensing devices in a next display frame according to the temperatures at the positions at which the temperature-sensing devices are located.
